(19) United States
(12) Patent Application Publication
(10) Pub. No.: US 2025/0038729 A1
(43) Pub. Date: Jan. 30, 2025

(54) METHOD FOR ADJUSTING FREQUENCY OF PIEZOELECTRIC RESONATOR DEVICE AND PIEZOELECTRIC RESONATOR DEVICE

(71) Applicant: DAISHINKU CORPORATION, Kakogawa-shi, Hyogo (JP)

(72) Inventors: Takuya KOJO, Kakogawa-shi (JP); Manabu ONISHI, Kakogawa-shi (JP)

(73) Assignee: DAISHINKU CORPORATION, Kakogawa-shi, Hyogo (JP)

(21) Appl. No.: 18/693,142

(22) PCT Filed: Sep. 22, 2022
(86) PCT No.: PCT/JP2022/035506

§ 371 Date: Mar. 18, 2024

(30) Foreign Application Priority Data
Sep. 30, 2021 (JP) 2021-161534

(51) Int. Cl. H03H 3/04; H03H 9/05; H03H 9/13; H03H 9/19

(52) U.S. Cl. CPC H03H 3/04; H03H 9/05; H03H 9/13; H03H 2003/0428; H03H 9/19

(57) ABSTRACT

In a method for adjusting a frequency of a crystal resonator, a frequency adjustment metal film made of a base metal layer and a metal layer laminated thereon is formed on a first main surface of a second sealing member on a side facing a second excitation electrode. The second sealing member is made of crystal. The frequency adjustment metal film is irradiated with a laser from the outside of the second sealing member so that the laser penetrates the interior of the second sealing member and heats the base metal layer. Then, at least part of the metal layer is melted and evaporated, and the evaporated metal is adhered to the second excitation electrode. Thus, the frequency adjustment is performed.

### TECHNICAL FIELD

The present invention relates to a method for adjusting a frequency of a piezoelectric resonator device and the piezoelectric resonator device.

### BACKGROUND ART

Conventionally, the manufacturing process of a piezoelectric resonator device such as a crystal resonator includes a frequency adjustment step. In this frequency adjustment step, the frequency of the crystal resonator is adjusted in a target frequency range (see, for example, Patent Document 1).

When the frequency adjustment step is performed after a vibrating part of a crystal resonator plate is sealed by a sealing member, a beam such as a laser is emitted from the outside of the crystal resonator. In this case, if the beam power is extremely large, an excitation electrode of the vibrating part may be damaged. Also, scattering matters and/or gas may be generated in the internal space of the crystal resonator.

### PRIOR ART DOCUMENT

### Patent Document

[Patent Document 1] JP 5762811

### SUMMARY OF THE INVENTION

### Problem to be Solved by the Invention

The present invention was made in consideration of the above circumstances, an object of which is to provide a method for adjusting a frequency of a piezoelectric resonator device. By this method, the frequency adjustment is easily performed even after a vibrating part of a piezoelectric resonator plate is sealed by a sealing member, without degrading the characteristics of the piezoelectric resonator device. Furthermore, another object of the present invention is to provide a piezoelectric resonator device capable of reducing long time changes of its frequency.

### Means for Solving the Problem

The present invention provides the means for solving the above-described problems as specified below. That is, the present invention provides a method for adjusting a frequency of a piezoelectric resonator device in which a piezoelectric resonator plate includes a vibrating part having an excitation electrode thereon and at least the vibrating part is hermetically sealed by a sealing member. A frequency adjustment metal film made of a base metal layer and a metal layer laminated thereon is formed on a main surface of the sealing member on a side facing the excitation electrode. At least a part of the sealing member on which the frequency adjustment metal film is formed is made of a transparency material. The frequency adjustment metal film is irradiated with a beam from an outside of the sealing member so that the beam penetrates an interior of the sealing member, heats the base metal layer, and thus melts and evaporates (turns into gas) at least part of the metal layer. The evaporated metal is adhered to the excitation electrode so as to adjust the frequency.

With the method for adjusting the frequency of the piezoelectric resonator device as described above, the metal layer laminated on the base metal layer is melted and evaporated, and the evaporated metal is adhered to the excitation electrode to increase the mass of the excitation electrode. Thus, the frequency can be shifted to the lower side. In this case, by controlling the beam power, the irradiation time and the like, it is possible to obtain the desired amount of the frequency adjustment. Also, by preventing the beam from penetrating the frequency adjustment metal film, it is possible to avoid damaging the excitation electrode. Therefore, it is possible to perform the frequency adjustment without considerably degrading the characteristics of the piezoelectric resonator device even after sealing the vibrating part of the piezoelectric resonator plate by the sealing member.

In the above-described method for adjusting the frequency of the piezoelectric resonator device, it is preferable that the beam is emitted not to penetrate the base metal layer but to melt the metal layer. In this way, since the beam does not penetrate the frequency adjustment metal film, it is possible to more reliably avoid damaging the excitation electrode. Therefore, it is possible to easily perform the frequency adjustment without considerably degrading the characteristics of the piezoelectric resonator device even after sealing the vibrating part of the piezoelectric resonator plate by the sealing member.

In the above-described method for adjusting the frequency of the piezoelectric resonator device, it is preferable, in the frequency adjustment metal film, that the melting temperature (melting point) of the base metal layer is higher than the melting temperature of the metal layer. In this case, it is also preferable that the difference between the melting temperature of the base metal layer and the melting temperature of the metal layer is 350 K or more. Furthermore, in the case where the metal layer is made of a plurality of metal layers, it is preferable that the difference between the melting temperature of the base metal layer and the melting temperature of an uppermost one of the plurality of metal layers is 350 K or more. Like this, there is a difference between the melting temperature of the base metal layer and the melting temperature of the metal layer. Thus, by heating, by laser irradiation, the base metal layer to a temperature in the range from the melting temperature or more of the metal layer to the melting temperature or less of the base metal layer, only the metal layer is melted while the base metal layer is not melted. Thus, part of the melted metal can be evaporated. The evaporated metal is adhered to the excitation electrode to increase the mass of the excitation electrode, which shifts the frequency to the lower side. Therefore, it is possible to easily perform the frequency adjustment without considerably degrading the characteristics of the piezoelectric resonator device even after sealing the vibrating part of the piezoelectric resonator plate by the sealing member.

In the above-described method for adjusting the frequency of the piezoelectric resonator device, it is preferable that, in the sealing member, a first main surface on which the frequency adjustment metal film is formed and a second main surface opposite to the first main surface are each formed as a smooth flat surface. In this way, it is possible to prevent beam reflection and beam refraction when the beam enters the second main surface of the sealing member and when the beam exits from the first main surface of the sealing member, which leads to reduction in energy loss of the beam. Therefore, it is possible to perform the frequency adjustment with high accuracy according to the beam power, the irradiation time and the like even after sealing the vibrating part of the piezoelectric resonator plate by the sealing member.

In the above-described method for adjusting the frequency of the piezoelectric resonator device, it is preferable that the metal layer is made of the same material as that of the excitation electrode. In this way, since the metal layer is made of the same material as that of the excitation electrode, the characteristics before the frequency adjustment do not change after the frequency adjustment. Thus, it is possible to prevent the characteristics of the piezoelectric resonator device from changing after the sealing.

In the above-described method for adjusting the frequency of the piezoelectric resonator device, it is preferable that the base metal layer is made of titanium. In this way, by causing the base metal layer that is exposed to the internal space of the piezoelectric resonator device to function as a getter material, gas generated in the internal space of the piezoelectric resonator device can be captured by the base metal layer.

In the above-described method for adjusting the frequency of the piezoelectric resonator device, it is preferable that the beam is a visible light laser. In this way, by using, for example, the visible light laser that has low absorptivity and high transmittance with respect to the sealing member made of crystal or glass, it is possible to prevent loss of power and damage to the sealing member. Thus, this type of laser is suitable for the frequency adjustment.

In the above-described method for adjusting the frequency of the piezoelectric resonator device, it is preferable that a space in which the vibrating part of the piezoelectric resonator plate is sealed is in a vacuum state. In this way, the evaporated metal can be substantially linearly moved, which reduces scatter to the surroundings. Furthermore, it is possible to adhere the evaporated metal to the excitation electrode without lowering the temperature of the evaporated metal.

In the above-described method for adjusting the frequency of the piezoelectric resonator device, it is preferable that the distance between the excitation electrode and the frequency adjustment metal film in a vertical direction is 2 to 200 μm. In this way, since the distance between the excitation electrode and the frequency adjustment metal film is extremely small, it is possible to substantially linearly move the metal that is evaporated from the frequency adjustment metal film so that the evaporated metal is prevented from scattering to the surroundings. Thus, the evaporated metal can be adhered reliably to the excitation electrode, and accordingly, it is possible to easily perform the frequency adjustment with high accuracy even after sealing the vibrating part of the piezoelectric resonator plate by the sealing member.

In the above-described method for adjusting the frequency of the piezoelectric resonator device, it is preferable that the piezoelectric resonator device includes: a first sealing member that covers a first main surface of the vibrating part of the piezoelectric resonator plate; and a second sealing member that covers a second main surface of the vibrating part of the piezoelectric resonator plate. It is also preferable that the first sealing member is bonded to the piezoelectric resonator plate and the second sealing member is bonded to the piezoelectric resonator plate so that the vibrating part of the piezoelectric resonator plate is hermetically sealed. Furthermore, it is preferable that the first sealing member and the second sealing member are each made of crystal. Like this, when the piezoelectric resonator device having the three-layer structure is used, it is possible to make the piezoelectric resonator device smaller and thinner. And in such a piezoelectric resonator device made smaller and thinner, it is possible to perform the frequency adjustment with high accuracy even after sealing the vibrating part of the piezoelectric resonator plate by the first and second sealing members.

Also the present invention provides a piezoelectric resonator device in which a piezoelectric resonator plate includes a vibrating part having an excitation electrode thereon and at least the vibrating part is hermetically sealed by a sealing member. In the piezoelectric resonator device, a frequency adjustment metal film made of a base metal layer and a metal layer laminated thereon is formed on a main surface of the sealing member on a side facing the excitation electrode. At least a part of the base metal layer of the frequency adjustment metal film is not covered by the metal layer but is exposed.

With the piezoelectric resonator device as described above, it is possible to prevent adhesion of the frequency adjustment metal film and the excitation electrode even when the vibrating part is bent by an external impact. For example, when the base metal layer is made of a material different from that of the excitation electrode and when the base metal layer is not exposed, the metal layer laminated on the base metal layer and the excitation electrode may adhere (stick) to each other at the time when the vibrating part is bent by the external impact. On the other hand, when the base metal layer is made of a material different from that of the excitation electrode and when the base metal layer is not covered by the metal layer but is exposed, it is possible to prevent the adhesion of the base metal layer to the excitation electrode even when the vibrating part is bent by the external impact so that the exposed base metal layer comes into contact with the excitation electrode. Furthermore, by causing the exposed base metal layer to function as a getter material, gas generated in the internal space of the piezoelectric resonator device can be captured by the base metal layer. As an example of the material of such a base metal layer, titanium or the like is preferable. Thus, it is possible to reduce long time changes of the frequency of the piezoelectric resonator device caused by generation of gas.

In the above-described piezoelectric resonator device, it is preferable that the piezoelectric resonator plate includes: the vibrating part; and an external frame part surrounding the vibrating part. In this way, it is possible to make the distance between the excitation electrode and the frequency adjustment metal film extremely small compared to the configuration in which the sealing member is bonded to the base using adhesive. Accordingly, it is possible to perform the frequency adjustment with high accuracy.

Preferably, the above-described piezoelectric resonator device further includes: a first sealing member that covers a first main surface of the vibrating part of the piezoelectric resonator plate; and a second sealing member that covers a second main surface of the vibrating part of the piezoelectric resonator plate. It is also preferable that the first sealing member is bonded to the piezoelectric resonator plate and furthermore the second sealing member is bonded to the piezoelectric resonator plate so that the vibrating part of the piezoelectric resonator plate is hermetically sealed. Furthermore, it is preferable that the first sealing member and the second sealing member are each made of crystal. Like this, when the piezoelectric resonator device having the three-layer structure is used, it is possible to make the piezoelectric resonator device smaller and thinner. And in such a piezoelectric resonator device made smaller and thinner, it is possible to reduce long time changes of the frequency.

### Effects of the Invention

With the method for adjusting a frequency of a piezoelectric resonator device of the present invention, the metal layer laminated on the base metal layer is melted and evaporated, and the evaporated metal is adhered to the excitation electrode to increase the mass of the excitation electrode. Thus, the frequency can be shifted to the lower side. Also, by preventing the beam from penetrating the frequency adjustment metal film, it is possible to avoid damaging the excitation electrode. Therefore, it is possible to perform the frequency adjustment without considerably degrading the characteristics of the piezoelectric resonator device even after sealing the vibrating part of the piezoelectric resonator plate by the sealing member. Also, with the piezoelectric resonator device of the present invention, it is possible to prevent adhesion of the frequency adjustment metal film and the excitation electrode even when the vibrating part is bent by an external impact. Furthermore, by causing the exposed base metal layer to function as a getter material, gas generated in the internal space of the piezoelectric resonator device can be captured by the base metal layer. Thus, it is possible to reduce long time changes of the frequency of the piezoelectric resonator device caused by generation of gas.

### BRIEF DESCRIPTION OF THE DRAWINGS

FIG. 1 is a schematic configuration diagram schematically illustrating a configuration of a crystal resonator according to an embodiment.

FIG. 2 is a schematic plan view illustrating a first main surface of a first sealing member of the crystal resonator.

FIG. 3 is a schematic plan view illustrating a second main surface of the first sealing member of the crystal resonator.

FIG. 4 is a schematic plan view illustrating a first main surface of a crystal resonator plate according to the embodiment.

FIG. 5 is a schematic plan view illustrating a second main surface of the crystal resonator plate according to the embodiment.

FIG. 6 is a schematic plan view illustrating a first main surface of a second sealing member of the crystal resonator.

FIG. 7 is a schematic plan view illustrating a second main surface of the second sealing member of the crystal resonator.

FIG. 8 is a schematic cross-sectional view schematically illustrating a method for adjusting the frequency of the crystal resonator according to the embodiment.

FIG. 9 is a schematic cross-sectional view schematically illustrating a frequency adjustment metal film of the crystal resonator according to the embodiment.

FIG. 10 is a cross-sectional view corresponding to FIG. 8, which illustrates a method for adjusting the frequency of the crystal resonator according to Variation 1.

FIG. 11 is a cross-sectional view corresponding to FIG. 8, which illustrates a method for adjusting the frequency of the crystal resonator according to Variation 2.

FIG. 12 is a plan view corresponding to FIG. 7, which illustrates a method for adjusting the frequency of the crystal resonator according to Variation 3.

FIG. 13 is a cross-sectional view corresponding to FIG. 8, which illustrates a method for adjusting the frequency of the crystal resonator according to Variation 4.

### MODE FOR CARRYING OUT THE INVENTION

Hereinafter, an embodiment of the present invention will be described in detail with reference to the drawings. In the embodiment below, a piezoelectric resonator device to which the present invention is applied is exemplarily shown as a crystal resonator.

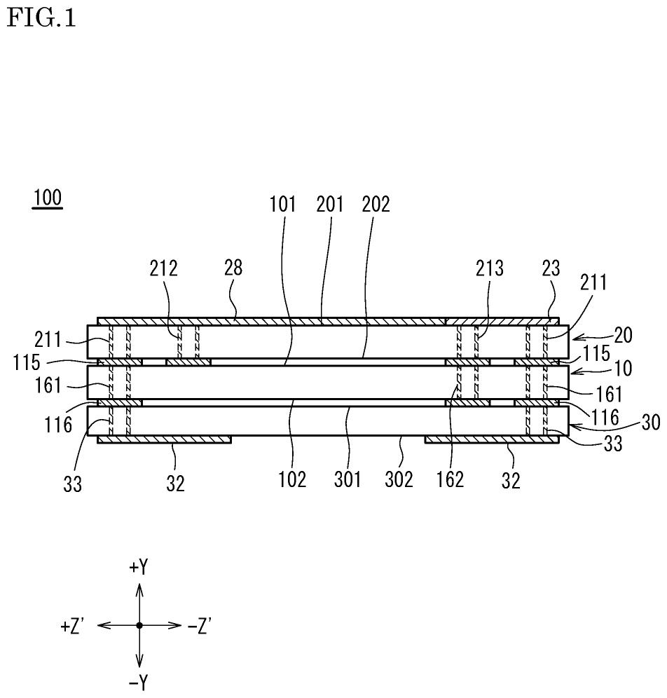

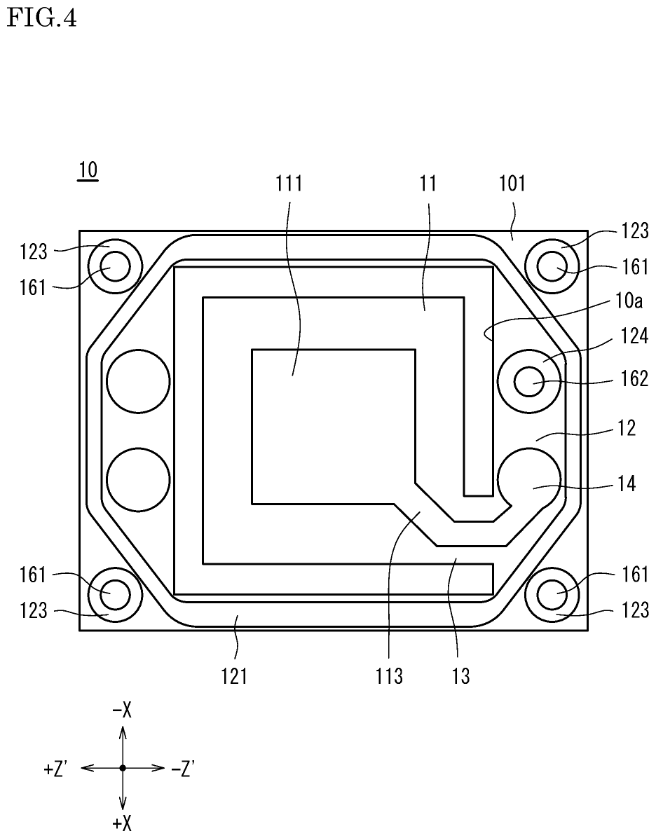

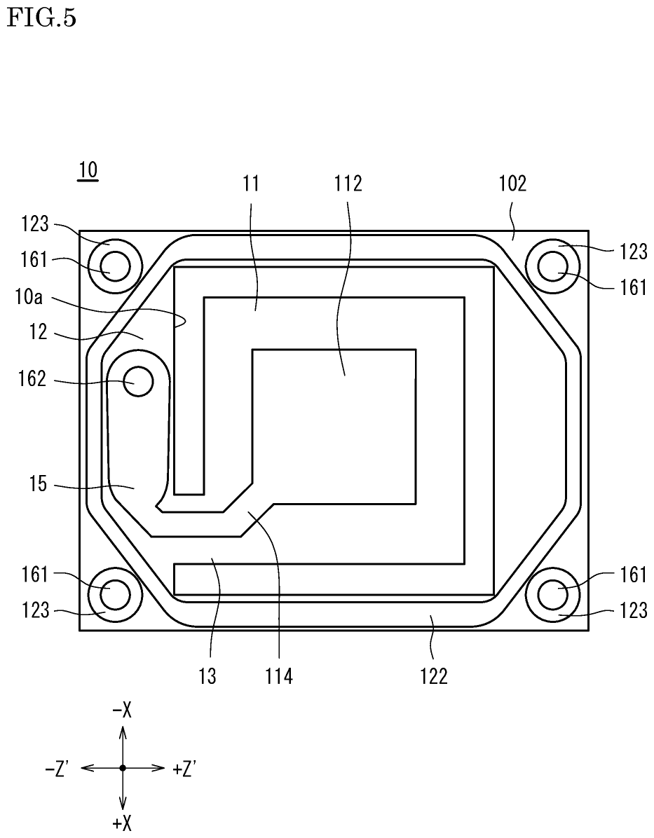

First, a basic configuration of a crystal resonator 100 according to this embodiment is described. As shown in FIG. 1, the crystal resonator 100 includes: a crystal resonator plate (piezoelectric resonator plate) 10; a first sealing member 20; and a second sealing member 30. In this crystal resonator 100, the crystal resonator plate 10 is bonded to the first sealing member 20, and furthermore the crystal resonator plate 10 is bonded to the second sealing member 30. Thus, a package having a sandwich structure is formed so as to have a substantially rectangular parallelepiped shape. That is, in the crystal resonator 100, the first sealing member 20 and the second sealing member 30 are bonded to respective main surfaces of the crystal resonator plate 10, thus an internal space (cavity) of the package is formed. In this internal space, a vibrating part 11 (see FIGS. 4 and 5) is hermetically sealed.

The crystal resonator 100 according to this embodiment has, for example, a package size of 1.0×0.8 mm, which is reduced in size and height. According to the size reduction, no castellation is formed in the package. Through holes are used for conduction between electrodes, as described later. The crystal resonator 100 is electrically connected to an external circuit board (not shown) provided outside via solder.

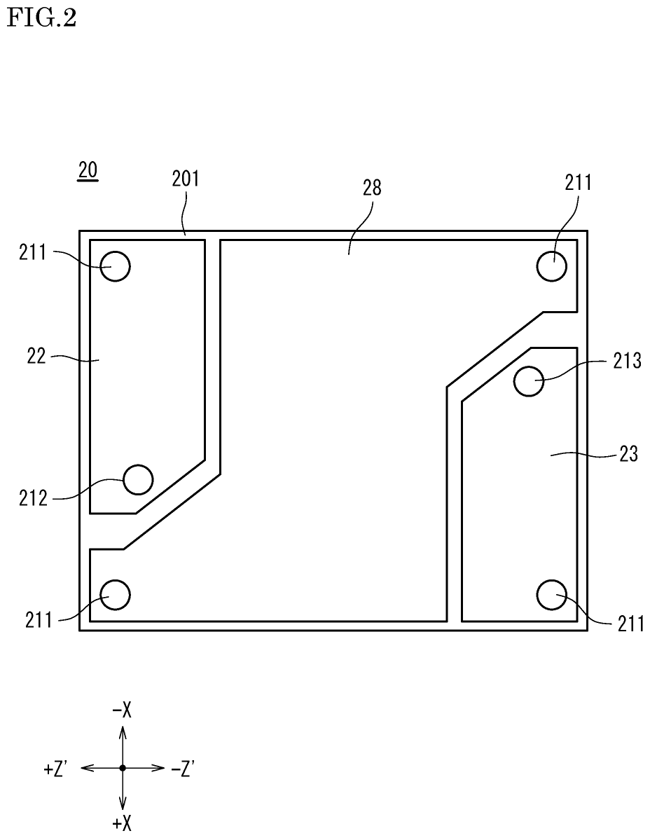

Next, the respective components of the above-described crystal resonator 100 (i.e. the crystal resonator plate 10, the first sealing member 20 and the second sealing member 30) are described with reference to FIGS. 1 to 7. Here, each of the components is described as a single body without being bonded. FIGS. 2 to 7 merely show respective configuration examples of the crystal resonator plate 10, the first sealing member 20 and the second sealing member 30, and thus the present invention is not limited thereto.

The crystal resonator plate 10 according to this embodiment is a piezoelectric substrate made of crystal as shown in FIGS. 4 and 5. Each main surface (i.e. a first main surface 101 and a second main surface 102) is formed as a smooth flat surface by polishing (mirror finishing). In this embodiment, an AT-cut crystal plate that causes thickness shear vibration is used as the crystal resonator plate 10. In the crystal resonator plate 10 shown in FIGS. 4 and 5, each of the main surfaces 101 and 102 of the crystal resonator plate 10 is an XZ′ plane. On this XZ′ plane, the direction parallel to the lateral direction (short side direction) of the crystal resonator plate 10 is the X axis direction, and the direction parallel to the longitudinal direction (long side direction) of the crystal resonator plate 10 is the Z′ axis direction. The AT-cut method is a processing method in which a crystal plate is cut out of synthetic quartz crystal at an angle tilted by 35° 15″ about the X axis from the Z axis, out of the three crystal axes (i.e. an electrical axis (X axis), a mechanical axis (Y axis) and an optical axis (Z axis)) of the synthetic quartz crystal. The X axis of the AT-cut crystal plate equals the crystal axis of the crystal. The Y′ axis and the Z′ axis equal the respective axes that tilt by approximately 35° 15′ from the Y axis and the Z axis out of the crystal axes of the crystal (this cutting angle may be changed to a certain extent within the range in which the frequency temperature characteristics of the AT-cut crystal resonator plate can be adjusted). The Y′ axis direction and the Z′ axis direction correspond to the directions in which the AT-cut crystal is cut out.

A pair of excitation electrodes (i.e. a first excitation electrode 111 and a second excitation electrode 112) is formed, respectively, on the main surfaces 101 and 102 of the crystal resonator plate 10. The crystal resonator plate 10 includes: the vibrating part 11 formed so as to have a substantially rectangular shape; an external frame part 12 surrounding the outer periphery of the vibrating part 11; and a support part (connection part) 13 that supports the vibrating part 11 by connecting the vibrating part 11 to the external frame part 12. That is, the crystal resonator plate 10 has a configuration in which the vibrating part 11, the external frame part 12 and the support part 13 are integrally formed. The support part 13 extends (protrudes) from only one corner part positioned in the +X direction and in the −Z′ direction of the vibrating part 11 to the external frame part 12 in the −Z′ direction. A penetrating part (slit) 10a is formed between the vibrating part 11 and the external frame part 12 so as to penetrate the crystal resonator plate 10 in the thickness direction. In this embodiment, the crystal resonator plate 10 has only one support part 13 to connect the vibrating part 11 to the external frame part 12. The penetrating part 10a is continuously formed so as to surround the outer periphery of the vibrating part 11.

The first excitation electrode 111 is provided on the first main surface 101 side of the vibrating part 11 while the second excitation electrode 112 is provided on the second main surface 102 side of the vibrating part 11. The first excitation electrode 111 and the second excitation electrode 112 are respectively connected to input and output lead-out wirings (i.e. a first lead-out wiring 113 and a second lead-out wiring 114) so that these excitation electrodes are connected to external electrode terminals. The first input lead-out wiring 113 is drawn from the first excitation electrode 111 and connected to a connection bonding pattern 14 formed on the external frame part 12 via the support part 13. The second output lead-out wiring 114 is drawn from the second excitation electrode 112 and connected to a connection bonding pattern 15 formed on the external frame part 12 via the support part 13.

Resonator-plate-side sealing parts to bond the crystal resonator plate 10 respectively to the first sealing member 20 and the second sealing member 30 are provided on the respective main surfaces (i.e. the first main surface 101 and the second main surface 102) of the crystal resonator plate 10. As the resonator-plate-side sealing part on the first main surface 101, a resonator-plate-side first bonding pattern 121 is formed. As the resonator-plate-side sealing part on the second main surface 102, a resonator-plate-side second bonding pattern 122 is formed. The resonator-plate-side first bonding pattern 121 and the resonator-plate-side second bonding pattern 122 are each formed on the external frame part 12 so as to have an annular shape in plan view.

Also, as shown in FIGS. 4 and 5, five through holes are formed in the crystal resonator plate 10 so as to penetrate between the first main surface 101 and the second main surface 102. More specifically, four first through holes 161 are respectively disposed in the four corners (corner parts) of the external frame part 12. A second through hole 162 is disposed in the external frame part 12, on one side in the Z′ axis direction relative to the vibrating part 11 (in FIGS. 4 and 5, on the side of the −Z′ direction). Connection bonding patterns 123 are formed on the respective peripheries of the first through holes 161. Also, on the periphery of the second through hole 162, a connection bonding pattern 124 is formed on the first main surface 101 side while the connection bonding pattern 15 is formed on the second main surface 102 side.

In the first through holes 161 and the second through hole 162, through electrodes are respectively formed along a corresponding inner wall surface of the above through holes so as to establish conduction between the electrodes formed on the first main surface 101 and the second main surface 102. Respective center parts of the first through holes 161 and the second through hole 162 are hollow penetrating parts penetrating between the first main surface 101 and the second main surface 102. The outer peripheral edge of the resonator-plate-side first bonding pattern 121 is disposed so as to be adjacent to the outer peripheral edge of the first main surface 101 of the crystal resonator plate 10 (external frame part 12). The outer peripheral edge of the resonator-plate-side second bonding pattern 122 is disposed so as to be adjacent to the outer peripheral edge of the second main surface 102 of the crystal resonator plate 10 (external frame part 12). In this embodiment, the configuration is exemplarily described, in which five through holes are formed so as to penetrate between the first main surface 101 and the second main surface 102. However, the through holes are not necessarily required to be formed. In place of the through holes, a castellation may be used by cutting out a part of the side surface of the first sealing member 20, and attaching an electrode to an inner wall surface of the cut-out region. (In this case, this configuration is also applied to the second sealing member 30).

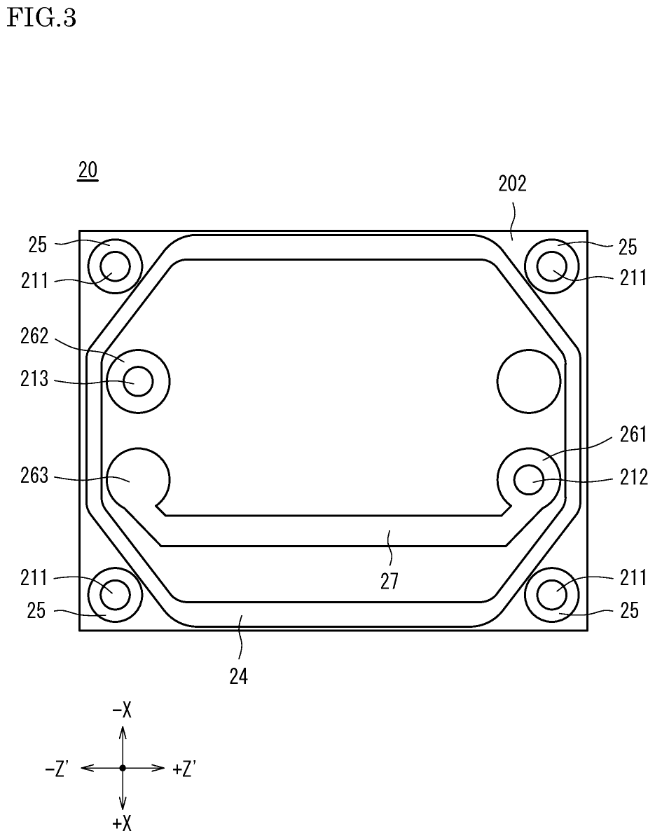

As shown in FIGS. 2 and 3, the first sealing member 20 is a substrate having a rectangular parallelepiped shape that is made of a single AT-cut crystal plate as a transparency material. A second main surface 202 (a surface to be bonded to the crystal resonator plate 10) of the first sealing member 20 is formed as a smooth flat surface by polishing (mirror finishing). By making the first sealing member 20, which does not have the vibrating part, of the AT-cut crystal plate as in the case of the crystal resonator plate 10, it is possible for the first sealing member 20 to have the same coefficient of thermal expansion as the crystal resonator plate 10. Thus, it is possible to prevent thermal deformation of the crystal resonator 100. Furthermore, the respective directions of the X axis, Y axis and Z′ axis of the first sealing member 20 are the same as those of the crystal resonator plate 10.

As shown in FIG. 2, a first and second terminals 22 and 23 for wiring and a metal film 28 for shielding (for earth connection) are formed on a first main surface 201 (the outer main surface not facing the crystal resonator plate 10) of the first sealing member 20. The first and second terminals 22 and 23 for wiring are provided as the wirings for electrically connecting respectively the first and second excitation electrodes 111 and 112 of the crystal resonator plate 10 to external electrode terminals 32 of the second sealing member 30. The first and second terminals 22 and 23 are respectively provided on both end parts in the Z′ direction. Specifically, the first terminal 22 is provided on the end part in the +Z′ direction while the second terminal 23 is provided on the end part in the −Z′ direction. The first and second terminals 22 and 23 are both formed so as to extend in the X axis direction. The first and second terminals 22 and 23 are each formed so as to have a substantially rectangular shape.

The metal film 28 is disposed between the first terminal 22 and the second terminal 23 at a predetermined distance from both the first terminal 22 and the second terminal 23. The metal film 28 is provided over almost the entire area of the first main surface 201 of the first sealing member 20, except for the area where the first terminal 22 and the second terminal 23 are provided. The metal film 28 is provided so as to cover from the end of the first main surface 201 of the first sealing member 20 in the +X direction to the end thereof in the −X direction.

As shown in FIGS. 2 and 3, six through holes are formed in the first sealing member 20 so as to penetrate between the first main surface 201 and the second main surface 202. More specifically, four third through holes 211 are respectively disposed in the four corners (corner parts) of the first sealing member 20. Fourth and fifth through holes 212 and 213 are disposed respectively in the +Z′ direction and in the −Z′ direction in FIGS. 2 and 3.

In the third through holes 211 and the fourth and fifth through holes 212 and 213, through electrodes are respectively formed along a corresponding inner wall surface of the above through holes so as to establish conduction between the electrodes formed on the first main surface 201 and the second main surface 202. Respective center parts of the third through holes 211 and the fourth and fifth through holes 212 and 213 are hollow penetrating parts penetrating between the first main surface 201 and the second main surface 202. The respective through electrodes of the two third through holes 211 and 211 that are diagonally positioned on the first main surface 201 of the first sealing member 20 (i.e. in FIGS. 2 and 3, the third through hole 211 positioned in the corner part in the +X direction and in the +Z′ direction and the third through hole 211 positioned in the corner part in the −X direction and in the −Z′ direction) are electrically connected via the metal film 28. Also, the through electrode of the third through hole 211 positioned in the corner part in the −X direction and in the +Z′ direction is electrically connected to the through electrode of the fourth through hole 212 via the first terminal 22. Furthermore, the through electrode of the third through hole 211 positioned in the corner part in the +X direction and in the −Z′ direction is electrically connected to the through electrode of the fifth through hole 213 via the second terminal 23.

On the second main surface 202 of the first sealing member 20, a sealing-member-side first bonding pattern 24 is formed as a sealing-member-side first sealing part so as to be bonded to the crystal resonator plate 10. The sealing-member-side first bonding pattern 24 is formed so as to have an annular shape in plan view. On the second main surface 202 of the first sealing member 20, connection bonding patterns 25 are respectively formed on the peripheries of the third through holes 211. A connection bonding pattern 261 is formed on the periphery of the fourth through hole 212, and a connection bonding pattern 262 is formed on the periphery of the fifth through hole 213. Furthermore, a connection bonding pattern 263 is formed on the side opposite to the connection bonding pattern 261 in the long axis direction of the first sealing member 20 (i.e. on the side of the −Z′ direction). The connection bonding pattern 261 and the connection bonding pattern 263 are connected to each other via a wiring pattern 27. The outer peripheral edge of the sealing-member-side first bonding pattern 24 is disposed so as to be adjacent to the outer peripheral edge of the second main surface 202 of the first sealing member 20.

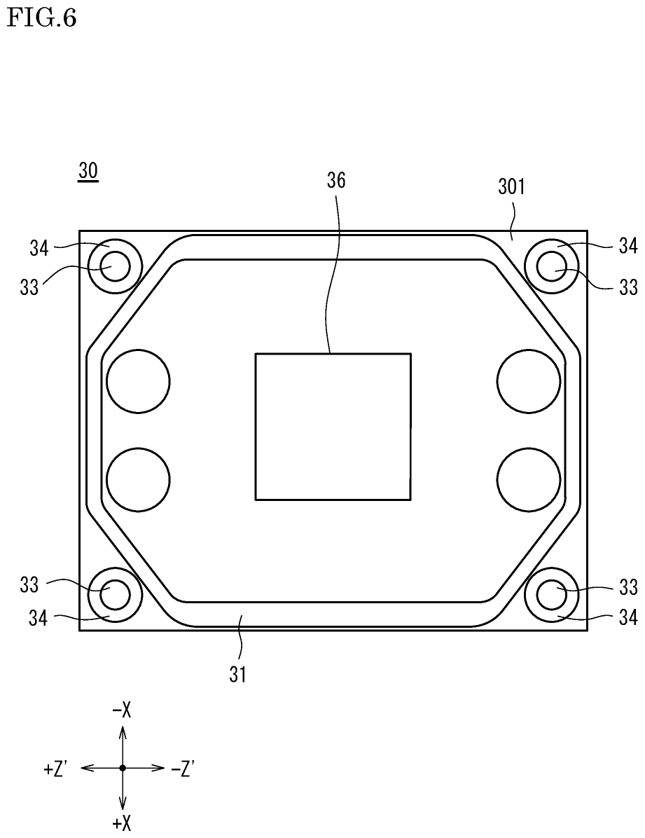

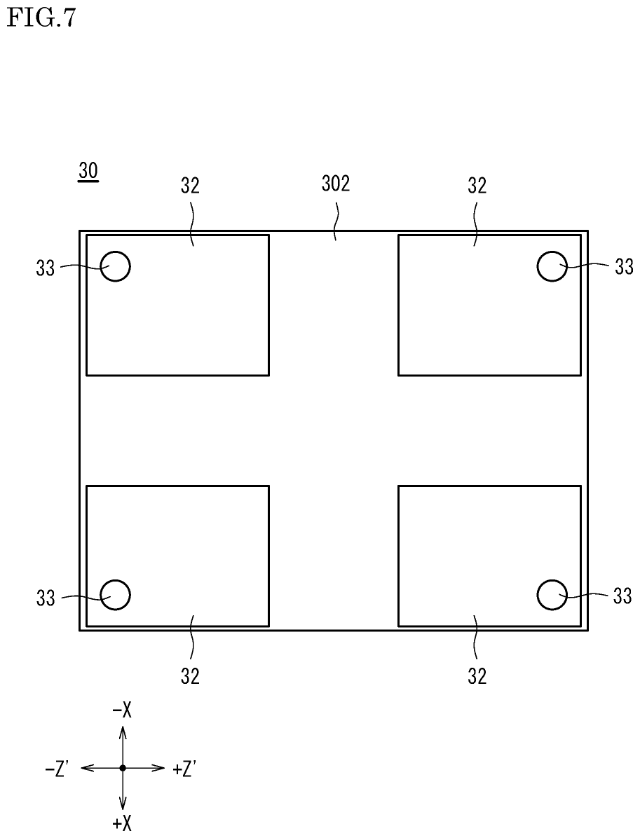

As shown in FIGS. 6 and 7, the second sealing member 30 is a substrate having a rectangular parallelepiped shape that is made of a single AT-cut crystal plate as a transparency material. A first main surface 301 (a surface to be bonded to the crystal resonator plate 10) and a second main surface 302 (an outer main surface not facing the crystal resonator plate 10) of the second sealing member 30 are each formed as a smooth flat surface by polishing (mirror finishing). The second sealing member 30 is also preferably made of an AT-cut crystal plate as in the case of the crystal resonator plate 10, and the respective directions of the X axis, Y axis and Z′ axis of the second sealing member 30 are preferably the same as those of the crystal resonator plate 10.

On the first main surface 301 of the second sealing member 30, a sealing-member-side second bonding pattern 31 is formed as a sealing-member-side second sealing part so as to be bonded to the crystal resonator plate 10. The sealing-member-side second bonding pattern 31 is formed so as to have an annular shape in plan view. The outer peripheral edge of the sealing-member-side second bonding pattern 31 is disposed so as to be adjacent to the outer peripheral edge of the first main surface 301 of the second sealing member 30.

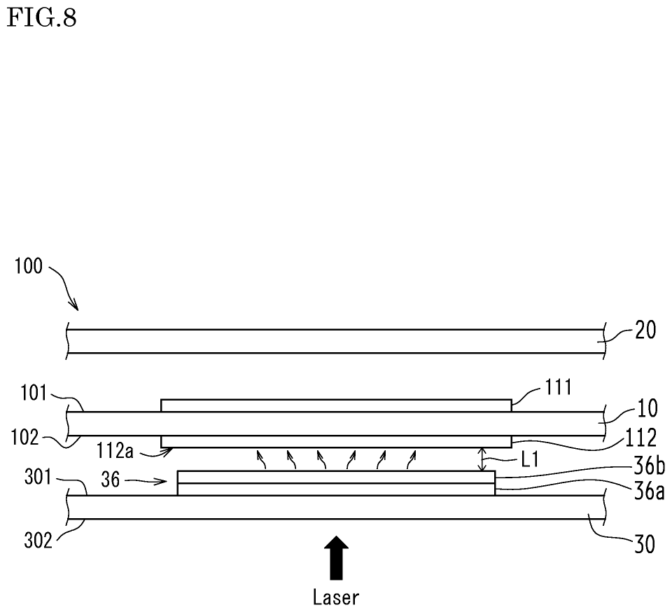

Also, on the first main surface 301 of the second sealing member 30, a frequency adjustment metal film 36 is formed so as to be used to adjust the frequency of the crystal resonator 100. The frequency adjustment metal film 36 has a two-layer structure made of two kinds of metals having different melting temperatures (melting points), and includes a base metal layer 36a and a metal layer 36b laminated on the base metal layer 36a as shown in FIG. 8. The base metal layer 36a has a thickness of, for example, 50 nm while the metal layer 36b has a thickness of, for example, 100 nm. The thickness of the base metal layer 36a is preferably 50 to 500 nm, and the thickness of the metal layer 36b is preferably 100 to 500 nm. It is not preferable that the thickness of the base metal layer 36a is less than 50 nm because such a base metal layer 36a cannot withstand the irradiation with the laser. Also, it is not preferable that the thickness of the base metal layer 36a is more than 500 nm because in such a base metal layer 36a, a wafer warps and the production efficiency is decreased due to layer thickness. It is not preferable that the thickness of the metal layer 36b is less than 100 nm because such a metal layer 36b cannot withstand the irradiation with the laser. Also, it is not preferable that the thickness of the metal layer 36b is more than 500 nm because in such a metal layer 36b, a wafer warps and the production efficiency is decreased due to layer thickness.

The base metal layer 36a is made of, for example, Ti (titanium), while the metal layer 36b is made of the same material as that of the second excitation electrode 112 (for example, Au). The melting temperature of the base metal layer 36a is higher than the melting temperature of the metal layer 36b. It is preferable that the difference between the melting temperature of the base metal layer 36a and the melting temperature of the metal layer 36b is 350 K or more. When the base metal layer 36a is made of Ti (titanium), its melting temperature is about 1941 K. When the metal layer 36b is made of Au (gold), its melting temperature is about 1337 K. Thus, the difference between the melting temperature of the base metal layer 36a and the melting temperature of the metal layer 36b is about 604 K. The base metal layer 36a may also be made of, for example, Ni (nickel). Furthermore, the metal layer 36b may have a multi-layer structure made of a plurality of metal layers. In this case, only the uppermost metal layer is needed to be made of the same material as that of the second excitation electrode 112 (for example, Au).

The frequency adjustment metal film 36 is disposed so as to face the second excitation electrode 112 at a predetermined interval. The distance L1 between the second excitation electrode 112 and the frequency adjustment metal film 36 in the vertical direction (the Y axis direction) is 2 to 200 μm.

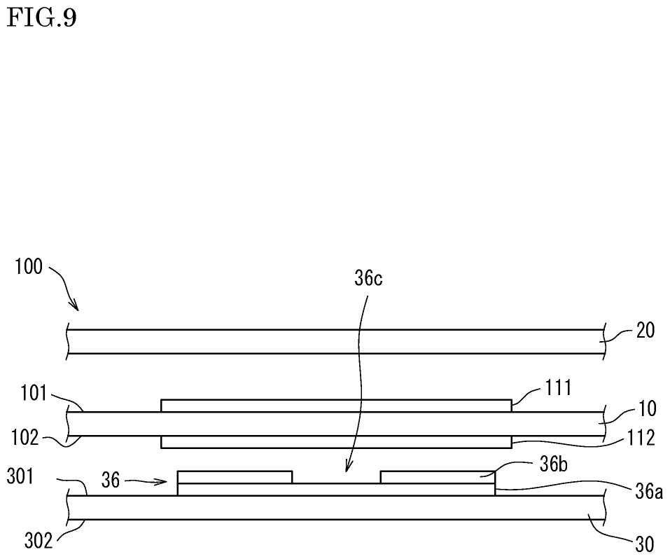

The frequency adjustment metal film 36 is formed in a substantially rectangular shape in plan view. The frequency adjustment metal film 36 is slightly smaller than the second excitation electrode 112 so that the outer peripheral edge of the frequency adjustment metal film 36 is located in the inside of the outer peripheral edge of the second excitation electrode 112 in plan view. Also, at least a part of the base metal layer 36a is not covered by the metal layer 36b but is exposed, and thus, a step part 36c (FIG. 9) is formed in the inside of the frequency adjustment metal film 36. With the above configuration, even when the vibrating part 11 is bent by an external impact so that the exposed part of the base metal layer 36a of the frequency adjustment metal film 36 comes into contact with the second excitation electrode 112, adhesion (sticking) of the base metal layer 36a to the second excitation electrode 112 can be prevented.

The first and second main surfaces 301 and 302 of the second sealing member 30 are each formed as a smooth flat surface by polishing. The arithmetic average roughness Ra of the first and second main surfaces 301 and 302 is 1 nm or less. Also, the arithmetic average roughness Ra of the surface of the metal layer 36b of the frequency adjustment metal film 36 is 3 nm or less.

On the second main surface 302 of the second sealing member 30, four external electrode terminals 32 are formed, which are electrically connected to an external circuit board provided outside the crystal resonator 100. The external electrode terminals 32 are respectively located on four corners (corner parts) on the second main surface 302 of the second sealing member 30.

As shown in FIGS. 6 and 7, four through holes are formed in the second sealing member 30 so as to penetrate between the first main surface 301 and the second main surface 302. More specifically, four sixth through holes 33 are respectively disposed in the four corners (corner parts) of the second sealing member 30. In the sixth through holes 33, through electrodes are respectively formed along a corresponding inner wall surface of the sixth through holes 33 so as to establish conduction between the electrodes formed on the first main surface 301 and the second main surface 302. In this way, the respective electrodes formed on the first main surface 301 are electrically conducted to the external electrode terminals 32 formed on the second main surface 302 via the through electrodes formed along the inner wall surfaces of the sixth through holes 33. Also, respective central parts of the sixth through holes 33 are hollow penetrating parts penetrating between the first main surface 301 and the second main surface 302. On the first main surface 301 of the second sealing member 30, connection bonding patterns 34 are respectively formed on the peripheries of the sixth through holes 33.

In the crystal resonator 100 including the crystal resonator plate 10, the first sealing member 20 and the second sealing member 30 as described above, the crystal resonator plate 10 and the first sealing member 20 are subjected to the diffusion bonding in a state in which the resonator-plate-side first bonding pattern 121 and the sealing-member-side first bonding pattern 24 are superimposed on each other, and the crystal resonator plate 10 and the second sealing member 30 are subjected to the diffusion bonding in a state in which the resonator-plate-side second bonding pattern 122 and the sealing-member-side second bonding pattern 31 are superimposed on each other, thus, the package having the sandwich structure as shown in FIG. 1 is produced. Accordingly, the internal space of the package, i.e. the space to house the vibrating part 11 is hermetically sealed.

In this case, the respective connection bonding patterns as described above are also subjected to the diffusion bonding in a state in which they are each superimposed on the corresponding connection bonding pattern. Such bonding between the connection bonding patterns allows electrical conduction of the first excitation electrode 111, the second excitation electrode 112 and the external electrode terminals 32 of the crystal resonator 100. More specifically, the first excitation electrode 111 is connected to the external electrode terminal 32 via the first lead-out wiring 113, the wiring pattern 27, the fourth through hole 212, the first terminal 22, the third through hole 211, the first through hole 161 and the sixth through hole 33 in this order. The second excitation electrode 112 is connected to the external electrode terminal 32 via the second lead-out wiring 114, the second through hole 162, the fifth through hole 213, the second terminal 23, the third through hole 211, the first through hole 161 and the sixth through hole 33 in this order. Also, the metal film 28 is earth-connected (i.e. ground connection, using parts of the external electrode terminals 32) via the third through holes 211, the first through holes 161 and the sixth through holes 33 in this order.

In the crystal resonator 100, the bonding patterns are each preferably made of a plurality of layers laminated on the crystal plate, specifically, a Ti (titanium) layer and an Au (gold) layer deposited, by vapor deposition or sputtering, in this order from the lowermost layer side. Also, the other wirings and electrodes formed on the crystal resonator 100 each preferably have the same configuration as the bonding patterns, which leads to patterning of the bonding patterns, wirings and the electrodes at the same time.

In the above-described crystal resonator 100, sealing parts (seal paths) 115 and 116 that hermetically seal the vibrating part 11 of the crystal resonator plate 10 are formed so as to have an annular shape in plan view. The seal path 115 is formed by the diffusion bonding (Au—Au bonding) of the resonator-plate-side first bonding pattern 121 and the sealing-member-side first bonding pattern 24 as described above. The outer edge and the inner edge of the seal path 115 both have a substantially octagonal shape. In the same way, the seal path 116 is formed by the diffusion bonding (Au—Au bonding) of the resonator-plate-side second bonding pattern 122 and the sealing-member-side second bonding pattern 31 as described above. The outer edge and the inner edge of the seal path 116 both have a substantially octagonal shape.

Here, a description is given on the frequency adjustment method of the crystal resonator 100 according to this embodiment with reference to FIG. 8. The frequency adjustment in this embodiment is a step of adjusting the mass of the second excitation electrode 112 of the vibrating part 11 of the crystal resonator plate 10 so as to adjust the oscillation frequency to a desired value. The frequency adjustment is performed to each crystal resonator 100 in a state of a wafer in the manufacturing process of the crystal resonator 100. Alternatively, the frequency adjustment may be performed to the crystal resonator 100 as each individual piece processed from the wafer.

As specifically shown in FIG. 8, the frequency adjustment metal film 36 is irradiated with a laser from the outside of the second sealing member 30 so that the laser penetrates the interior of the second sealing member 30 and heats the base metal layer 36a. Thus, at least part of the metal layer 36b is melted and evaporated (turned into gas), and the evaporated metal is adhered to the second excitation electrode 112. In this way, the frequency adjustment is performed. That is, the metal layer 36b disposed on the base metal layer 36a is melted and evaporated by the laser, and the evaporated metal is adhered to the second excitation electrode 112 to increase the mass of the second excitation electrode 112. Thus, the frequency is shifted to the lower side.

The laser is emitted perpendicularly to the second sealing member 30. As the laser, a visible light laser is used, which can penetrate the second sealing member 30 made of crystal. In particular, it is possible to use a green laser with the wavelength of about 532 nm. The value of the laser power is adjusted so as not to penetrate the base metal layer 36a of the frequency adjustment metal film 36. When the base metal layer 36a is heated by the laser, the metal layer 36b disposed on the base metal layer 36a is also heated. As described above, the melting temperature of the base metal layer 36a is higher than the melting temperature of the metal layer 36b. Thus, when the base metal layer 36a is heated so as to have a temperature higher than the melting temperature of the metal layer 36b, the metal layer 36b is melted, and part of the melted metal layer 36b is evaporated. Since the inside of the crystal resonator 100 is in a vacuum state, the evaporated metal moves upward substantially linearly and when the evaporated metal reaches a surface 112a of the second excitation electrode 112, it is cooled by the surface 112a of the second excitation electrode 112 so as to be solidified. In this way, the metal evaporated from the frequency adjustment metal film 36 is adhered to the surface 112a of the second excitation electrode 112.

It is possible to control the mass of the metal that is adhered to the second excitation electrode 112 by controlling the number of pulses, the sweep distance, the number of sweeps and the like of the laser emitted to the base metal layer 36a, which leads to control of the amount of the frequency adjustment. For example, by continuously irradiating with the laser whose power and pulse interval are reduced, the base metal layer 36a can be efficiently heated to evaporate only the metal layer 36b. In this case, it is possible to obtain the amount of the frequency adjustment according to the sweep distance of the laser, which leads to the frequency adjustment with high accuracy.

With the frequency adjustment method of the crystal resonator 100 in this embodiment, the metal layer 36b laminated on the base metal layer 36a is melted and evaporated, and the evaporated metal is adhered to the second excitation electrode 112 to increase the mass of the second excitation electrode 112. Thus, the frequency can be shifted to the lower side. In this case, by controlling the number of pulses, the sweep distance and the like of the laser, it is possible to obtain the desired amount of the frequency adjustment. Also, by preventing the laser from penetrating the frequency adjustment metal film 36, it is possible to avoid damaging the second excitation electrode 112. Therefore, it is possible to perform the frequency adjustment without considerably degrading the characteristics of the crystal resonator 100 even after sealing the vibrating part 11 of the crystal resonator plate 10 by the first and second sealing members 20 and 30.

In this embodiment, the laser is emitted so as not to penetrate the base metal layer 36a. Since the laser does not penetrate the frequency adjustment metal film 36, it is possible to more reliably avoid damaging the second excitation electrode 112. Therefore, it is possible to easily perform the frequency adjustment without considerably degrading the characteristics of the crystal resonator 100 even after sealing the vibrating part 11 of the crystal resonator plate 10 by the first and second sealing members 20 and 30.

In this embodiment, the difference between the melting temperature of the base metal layer 36a and the melting temperature of the metal layer 36b is 350 K or more. By heating, by laser irradiation, the base metal layer 36a so as to have a temperature in the range from the melting temperature or more of the metal layer 36b to the melting temperature or less of the base metal layer 36a, only the metal layer 36b is melted while the base metal layer 36a is not melted. Thus, part of the melted metal can be evaporated. The evaporated metal is adhered to the second excitation electrode 112 to increase the mass of the second excitation electrode 112, which shifts the frequency to the lower side. Therefore, it is possible to easily perform the frequency adjustment without considerably degrading the characteristics of the crystal resonator 100 even after sealing the vibrating part 11 of the crystal resonator plate 10 by the first and second sealing members 20 and 30.

In this embodiment, the first main surface 301 and the second main surface 302 opposite to the first main surface 301, of the second sealing member 30 are both formed as a smooth flat surface. Thus, it is possible to prevent laser reflection and laser refraction when the laser enters the second main surface 302 of the second sealing member 30 and when the laser exits from the first main surface 301 of the second sealing member 30, which leads to reduction in energy loss of the laser. Therefore, it is possible to perform the frequency adjustment with high accuracy according to the number of pulses, the sweep distance, the number of sweeps and the like of the laser even after sealing the vibrating part 11 of the crystal resonator plate 10 by the first and second sealing members 20 and 30.

Also, the metal layer 36b is made of Au (gold) as in the case of the second excitation electrode 112, which means that the metal layer 36b is made of the same material as that of the second excitation electrode 112. Thus, the characteristics before the frequency adjustment do not change after the frequency adjustment. In this way, it is possible to prevent the characteristics of the crystal resonator 100 from changing after the sealing.

The base metal layer 36a is made of Ti (titanium). Thus, by causing the base metal layer 36a that is exposed to the internal space of the crystal resonator 100 to function as a getter material, gas generated in the internal space of the crystal resonator 100 can be captured by the base metal layer 36a. Here, the base metal layer 36a may be made of W (tungsten). In this case, it is possible to widen the difference in the melting temperatures of the base metal layer 36a (W) and the metal layer 36b (Au) as the upper layer. For example, this difference may be 1500 K or more.

As the laser, the visible light laser is, for example, used, which has low absorptivity and high transmittance with respect to the second sealing member 30 made of crystal or glass. This type of laser is suitable for the frequency adjustment, because it can prevent loss of power and damage to the second sealing member 30.

Also, since the space in which the vibrating part 11 of the crystal resonator plate 10 is sealed is in a vacuum state, the evaporated metal can be substantially linearly moved, which reduces scatter to the surroundings. Furthermore, it is possible to adhere the evaporated metal to the second excitation electrode 112 without lowering the temperature of the evaporated metal.

In this embodiment, the distance L1 between the second excitation electrode 112 and the frequency adjustment metal film 36 in the vertical direction is 2 to 200 μm. In this way, since the distance L1 between the second excitation electrode 112 and the frequency adjustment metal film 36 is extremely small, it is possible to substantially linearly move the metal that is evaporated from the frequency adjustment metal film 36 so that the evaporated metal is prevented from scattering to the surroundings. Thus, the evaporated metal can be adhered reliably to the second excitation electrode 112, and accordingly, it is possible to easily perform the frequency adjustment with high accuracy even after sealing the vibrating part 11 of the crystal resonator plate 10 by the first and second sealing members 20 and 30.

Also, since the outer peripheral edge of the frequency adjustment metal film 36 is located inside of the outer peripheral edge of the second excitation electrode 112 in plan view, even when the vibrating part 11 is bent by an external impact so that the exposed part of the base metal layer 36a of the frequency adjustment metal film 36 comes into contact with the second excitation electrode 112, adhesion of the base metal layer 36a to the second excitation electrode 112 can be prevented. Furthermore, it is possible to prevent the metal evaporated from the frequency adjustment metal film 36 from scattering outside the second excitation electrode 112, which results in reliable adhesion of the evaporated metal to the second excitation electrode 112. Therefore, it is possible to easily perform the frequency adjustment with high accuracy even after sealing the vibrating part 11 of the crystal resonator plate 10 by the first and second sealing members 20 and 30.

In this embodiment, the crystal resonator 100 includes the first sealing member 20 that covers the first main surface of the vibrating part 11 of the crystal resonator plate 10 and the second sealing member 30 that covers the second main surface of the vibrating part 11 of the crystal resonator plate 10. The first sealing member 20 is bonded to the crystal resonator plate 10, and also the second sealing member 30 is bonded to the crystal resonator plate 10. Thus, the vibrating part 11 of the crystal resonator plate 10 is hermetically sealed. The first sealing member 20 and the second sealing member 30 are each made of crystal. Like this, when the crystal resonator 100 having the three-layer structure is used, it is possible to make the crystal resonator 100 smaller and thinner. And in such a crystal resonator 100 made smaller and thinner, it is possible to perform the frequency adjustment with high accuracy even after sealing the vibrating part 11 of the crystal resonator plate 10 by the first and second sealing members 20 and 30.

In the crystal resonator 100 in this embodiment described above, the frequency adjustment metal film 36 is formed on the first main surface 301 of the second sealing member 30, which faces the second excitation electrode 112. At least a part of the base metal layer 36a of the frequency adjustment metal film 36 is not covered by the metal layer 36b but is exposed. With this configuration, by causing the exposed base metal layer 36a to function as a getter material, gas generated in the internal space of the crystal resonator 100 can be captured by the base metal layer 36a. As an example of the material of the base metal layer 36a, titanium or the like is preferable. Thus, it is possible to reduce long time changes of the frequency of the crystal resonator 100 caused by generation of gas.

Since the crystal resonator plate 10 has a configuration including the vibrating part 11 and the external frame part 12 surrounding the vibrating part 11, it is possible to make the distance L1 between the second excitation electrode 112 and the frequency adjustment metal film 36 extremely small compared to the configuration in which the sealing member is bonded to the base using adhesive. Accordingly, it is possible to perform the frequency adjustment with high accuracy as described above.

The foregoing embodiment is to be considered in all respects as illustrative and not limiting. The technical scope of the invention is indicated by the appended claims rather than by the foregoing description, and all modifications and changes that come within the meaning and range of equivalency of the claims are intended to be embraced therein.

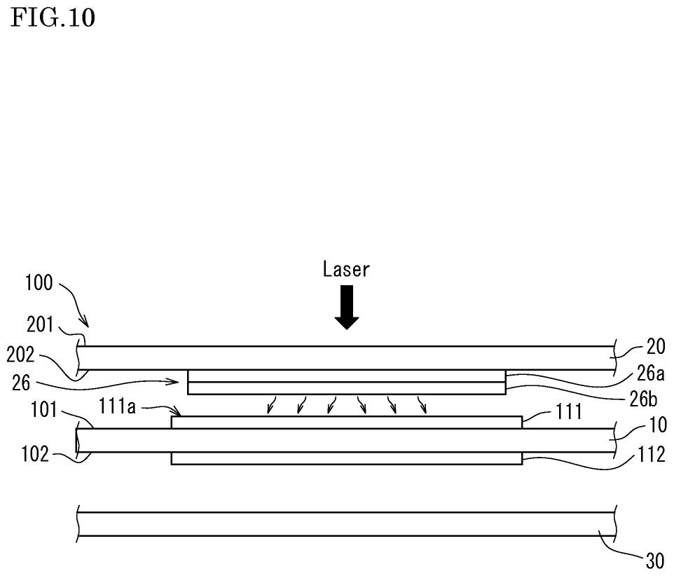

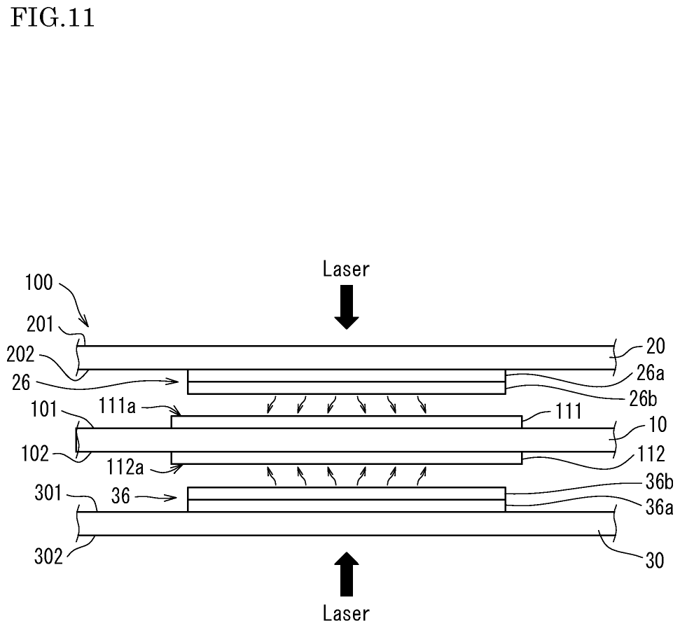

In the above-described embodiment, the frequency adjustment metal film 36 is formed on the first main surface 301 of the second sealing member 30, which faces the second excitation electrode 112. However, as shown in FIG. 10 as Variation 1, the frequency adjustment metal film is not necessarily required to be formed on the second sealing member 30, and it may be formed on the second main surface 202 of the first sealing member 20, which faces the first excitation electrode 111. Alternatively, as shown in FIG. 11 as Variation 2, a frequency adjustment metal film 26 may be formed on the second main surface 202 of the first sealing member 20 while the frequency adjustment metal film 36 is formed on the first main surface 301 of the second sealing member 30. The frequency adjustment metal film 26 on the first sealing member 20 has the same configuration as that of the frequency adjustment metal film 36 on the second sealing member 30 in the above-described embodiment. That is, the frequency adjustment metal film 26 is configured by a base metal layer 26a made of, for example, Ti (titanium) and a metal layer 26b made of the same material as the second excitation electrode 112 (for example, Au) and laminated on the base metal layer 26a.

In Variations 1 and 2 shown in FIGS. 10 and 11, an opening part having a rectangle shape in plan view is formed in the shield metal film 28 formed on the first main surface 201 of the first sealing member 20, so that the frequency adjustment by the frequency adjustment metal film 26 can be performed. The opening part is preferably formed so as to be size larger than the frequency adjustment metal film 26, and also it is preferable that the frequency adjustment metal film 26 is located so as to fall within this opening part in plan view.

With Variation 2 shown in FIG. 11, the frequency adjustment can be performed using both the frequency adjustment metal films 26 and 36. Thus, by also irradiating the frequency adjustment metal film 26 with the laser from the side of the first sealing member 20 of the crystal resonator 100, it is possible to perform the frequency adjustment on two sides, i.e. the side of the first sealing member 20 and the side of the second sealing member 30. In this case, the frequency adjustment may be simultaneously performed on the two sides of the first sealing member 20 and the second sealing member 30. Alternatively, the frequency adjustment may be performed on one side at a time in order. Or, the frequency adjustment may be performed using the frequency adjustment metal film 36 firstly, and if the amount of the frequency adjustment is insufficient compared to the desired mount of the frequency adjustment, then the frequency adjustment may be performed using the frequency adjustment metal film 26 so as to make up a deficiency.

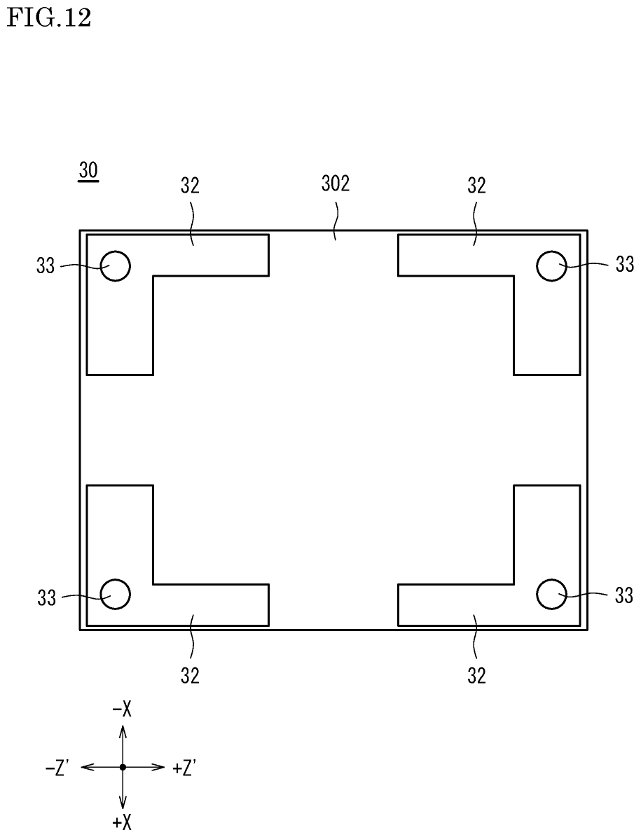

In the above-described embodiment, the external electrode terminals 32 provided on the second main surface 302 of the second sealing member 30 have a rectangle shape (see FIG. 7). However, as shown in FIG. 12 as Variation 3, the external electrode terminals 32 may have an L-shape. In this case, it is preferable that the external electrode terminals 32 are respectively located so as not to overlap with the internal space of the package in plan view. By forming the external electrode terminals 32 in the L-shape, the external electrode terminals 32 and the frequency adjustment metal film 36 do not overlap with each other in plan view even when the frequency adjustment metal film 36 is made larger. Therefore, it is possible to ensure a larger amount of the frequency adjustment.

In the above-described embodiment, the frequency adjustment is performed using the visible light laser. However, the frequency adjustment may be performed using another beam such as an electron beam. In this case, it is possible to obtain the desired amount of the frequency adjustment by controlling the beam power, the irradiation time and the like.

In the above-described embodiment, the step part 36c is formed in the center part of the frequency adjustment metal film 36 (see FIG. 9) so as to expose the base metal layer 36a. However, the step part 36c may be formed in at least a part of the frequency adjustment metal film 36. Also, the base metal layer 36a may be exposed at a part other than the outer peripheral edge, provided that the part is not irradiated with the laser.

In the above-described embodiment, the internal space of the crystal resonator 100 is in a vacuum state. However, low-pressure nitrogen or argon may be enclosed in the internal space of the crystal resonator 100.

In the above-described embodiment, the crystal resonator plate 10 is made of an AT-cut crystal plate. However, another type of crystal plate may be used. Also in the above-described embodiment, the vibrating part 11 of the crystal resonator plate 10 has a rectangle shape. However, the vibrating part may have a tuning fork shape.

In the above-described embodiment, the first sealing member 20 and the second sealing member 30 are each made of a crystal plate. However, the first sealing member 20 and the second sealing member 30 may be made of, for example, glass. In this case, an infrared laser may be used, which can penetrate the first sealing member 20 and the second sealing member 30. As the infrared laser, a YAG laser with the wavelength of about 1064 nm can be used. Furthermore, only parts of the first sealing member 20 and the second sealing member 30 may be made of the transparency material such as crystal and glass.

In the above-described embodiment, the crystal resonator plate 10 has only one support part 13 to connect the vibrating part 11 to the external frame part 12. However, two or more support parts 13 may be provided. Also in the above-described embodiment, the penetrating part 10a is provided between the vibrating part 11 and the external frame part 12 so as to penetrate the crystal resonator plate 10 in the thickness direction. However, the crystal resonator plate not having the penetrating part may be used. Also in the above-described embodiment, the crystal resonator plate 10 with the frame body is used, which is provided with the vibrating part 11 and the external frame part 12 surrounding the vibrating part 11. However, the crystal resonator plate not having the external frame part may be used.

In the above-described embodiment, the number of the external electrode terminals 32 on the second main surface 302 of the second sealing member 30 is four. However, the present invention is not limited thereto. The number of the external electrode terminals 32 may be, for example, two, six, or eight. Also in the above-described embodiment, the present invention is applied to the crystal resonator 100. However, the present invention may also be applied to, for example, a crystal oscillator or the like. When the present invention is applied to the crystal oscillator, the beam may be emitted to the frequency adjustment metal film from the outside on the side of the sealing member on which the IC is not mounted. Specifically, the configuration is described below.

First, a description is given on the case of a crystal oscillator having a configuration in which other electronic component elements (e.g. an integrated circuit element including an oscillation circuit, a capacitor, and a resistor) are mounted on an upper surface of the above-described three-layer structured crystal resonator. In this case, before the electronic component element is mounted on the upper surface of the crystal resonator, the frequency adjustment is performed by emitting the beam from above the crystal resonator to the frequency adjustment metal film that is formed on the main surface of the first sealing member and that faces the first excitation electrode. Then, after the electronic component element is mounted on the upper surface of the crystal resonator, the frequency adjustment is performed by emitting the beam from below the crystal resonator to the frequency adjustment metal film that is formed on the main surface of the second sealing member and that faces the second excitation electrode.

Next, a description is given on the case of a crystal oscillator having a configuration (single package structure) in which the crystal resonator plate and the electronic component element are housed inside a base made of an insulating material such as ceramic, glass, and crystal. The base has a recess part, and a lid is bonded to the base. In this case, after the electronic component element (for example, an integrated circuit element) is mounted on an inner bottom surface of the recess part of the base, the crystal resonator plate is bonded to a step part inside the recess part such that the crystal resonator plate is located above the integrated circuit element. Then, the lid having the frequency adjustment metal film on a main surface thereof facing the crystal resonator plate is bonded to the base so as to close the recess part. After that, the frequency adjustment is performed by emitting the beam from the outside of the lid (from above).

In the above-described embodiment, the three-layer structured crystal resonator 100 is used, in which the crystal resonator plate 10 is interposed between the first sealing member 20 and the second sealing member 30. However, another-structured crystal resonator may also be used. Examples of the crystal resonator having the structure other than the three-layer structure include: a crystal resonator having the single package structure as described above; and a crystal resonator having a structure in which a frame member is formed on each outer peripheral edge of both main surfaces of the substrate (i.e. H-shaped package structure).

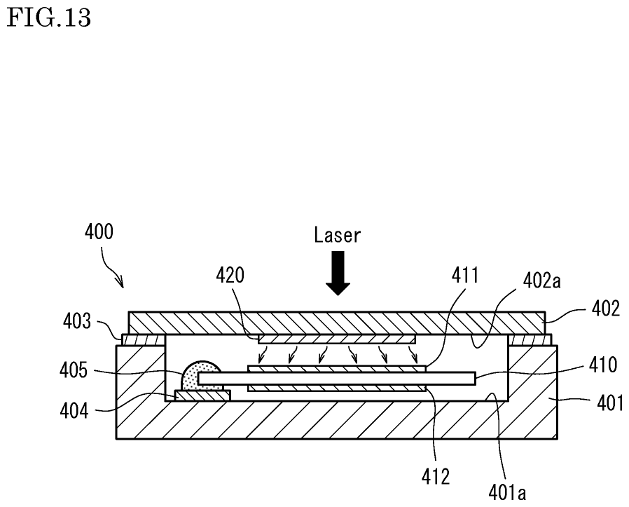

As shown in FIG. 13 as Variation 4, a single package structure crystal resonator 400 includes, for example: a base 401 made of ceramic; a lid 402 made of Si (silicon); a crystal resonator plate 410; and a frequency adjustment metal film 420. The base 401 is formed so as to have a substantially rectangular parallelepiped shape whose top part is opened. The opening part of the base 401 is closed with the lid 402 by bonding the lid 402 to the base 401 using a bonding material 403 (for example, AuSn or the like). The crystal resonator plate 410 is housed in the base 401. The crystal resonator plate 410 is connected to an electrode 404 formed on an inner bottom surface 401a of the base 401 by a conductive adhesive 405. On both main surfaces of the crystal resonator plate 410, first and second excitation electrodes 411 and 412 are respectively formed.

In the above single package structure crystal resonator 400, the frequency adjustment metal film 420 is formed on an inner surface 402a (a main surface facing the first excitation electrode 411) of the lid 402 as a sealing member. The frequency adjustment metal film 420 has the same configuration as that of the frequency adjustment metal films 26 and 36 in the above-described embodiment/variation, and thus has a base metal layer and a metal layer laminated on the base metal layer. The frequency adjustment metal film 420 is irradiated with a beam (for example, a YAG laser) from the outside of the lid 402 so that the beam penetrates the interior of the lid 402 and heats the base metal layer of the frequency adjustment metal film 420. Thus, at least part of the metal layer of the frequency adjustment metal film 420 is melted and evaporated, and the evaporated metal is adhered to the first excitation electrode 411. In this way, the frequency adjustment can be performed similarly to the above-described embodiment/variation. Here, a doping layer made of, for example, B (boron) or P (phosphorus) may be formed on the inner surface 402a (the main surface facing the first excitation electrode 411) of the lid 402. In this case, it is possible to provide the crystal resonator 400 having an EMI (electromagnetic interface)-prevention measure.

This application claims priority based on Patent Application No. 2021-161534 filed in Japan on Sep. 30, 2021. The entire contents thereof are hereby incorporated in this application by reference.

### DESCRIPTION OF THE REFERENCE NUMERALS

10 Crystal resonator plate (piezoelectric resonator plate)
20 First sealing member (sealing member)
30 Second sealing member (sealing member)
36 Frequency adjustment metal film
36a Base metal layer
36b Metal layer
100 Crystal resonator (piezoelectric resonator device)
111 First excitation electrode
112 Second excitation electrode
301 First main surface

1. A method for adjusting a frequency of a piezoelectric resonator device in which a piezoelectric resonator plate includes a vibrating part having an excitation electrode thereon and at least the vibrating part is hermetically sealed by a sealing member, wherein
a frequency adjustment metal film made of a base metal layer and a metal layer laminated thereon is formed on a main surface of the sealing member on a side facing the excitation electrode,
at least a part of the sealing member on which the frequency adjustment metal film is formed is made of a transparency material,
the frequency adjustment metal film is irradiated with a beam from an outside of the sealing member so that the beam penetrates an interior of the sealing member, heats the base metal layer, and thus melts and evaporates at least part of the metal layer, and
the evaporated metal is adhered to the excitation electrode so as to adjust the frequency.

2. The method for adjusting a frequency of a piezoelectric resonator device according to claim 1, wherein
the beam is emitted not to penetrate the base metal layer but to melt the metal layer.

3. The method for adjusting a frequency of a piezoelectric resonator device according to claim 1, wherein
in the frequency adjustment metal film, a melting temperature of the base metal layer is higher than a melting temperature of the metal layer.

4. The method for adjusting a frequency of a piezoelectric resonator device according to claim 3, wherein
a difference between the melting temperature of the base metal layer and the melting temperature of the metal layer is 350 K or more.

5. The method for adjusting a frequency of a piezoelectric resonator device according to claim 1, wherein
the metal layer is made of a plurality of metal layers, and
a difference between a melting temperature of the base metal layer and a melting temperature of an uppermost metal layer of the plurality of metal layers is 350 K or more.

6. The method for adjusting a frequency of a piezoelectric resonator device according to claim 1, wherein
in the sealing member, a first main surface on which the frequency adjustment metal film is formed and a second main surface opposite to the first main surface are each formed as a smooth flat surface.

7. The method for adjusting a frequency of a piezoelectric resonator device according to claim 1, wherein
the metal layer is made of a same material as that of the excitation electrode.

8. The method for adjusting a frequency of a piezoelectric resonator device according to claim 1, wherein
the base metal layer is made of titanium.

9. The method for adjusting a frequency of a piezoelectric resonator device according to claim 1, wherein
the beam is a visible light laser.

10. The method for adjusting a frequency of a piezoelectric resonator device according to claim 1, wherein
a space in which the vibrating part of the piezoelectric resonator plate is sealed is in a vacuum state.

11. The method for adjusting a frequency of a piezoelectric resonator device according to claim 1, wherein
a distance between the excitation electrode and the frequency adjustment metal film in a vertical direction is 2 to 200 μm.

12. The method for adjusting a frequency of a piezoelectric resonator device according to claim 1, wherein
the piezoelectric resonator device includes: a first sealing member that covers a first main surface of the vibrating part of the piezoelectric resonator plate; and a second sealing member that covers a second main surface of the vibrating part of the piezoelectric resonator plate,
the first sealing member is bonded to the piezoelectric resonator plate and furthermore the second sealing member is bonded to the piezoelectric resonator plate so that the vibrating part of the piezoelectric resonator plate is hermetically sealed, and
the first sealing member and the second sealing member are each made of crystal.

13. A piezoelectric resonator device in which a piezoelectric resonator plate includes a vibrating part having an excitation electrode thereon and at least the vibrating part is hermetically sealed by a sealing member, wherein
a frequency adjustment metal film made of a base metal layer and a metal layer laminated thereon is formed on a main surface of the sealing member on a side facing the excitation electrode, and
at least a part of the base metal layer of the frequency adjustment metal film is not covered by the metal layer but is exposed.

14. The piezoelectric resonator device according to claim 13, wherein
the piezoelectric resonator plate includes: the vibrating part; and an external frame part surrounding the vibrating part.

15. The piezoelectric resonator device according to claim 13, further comprising: a first sealing member that covers a first main surface of the vibrating part of the piezoelectric resonator plate; and a second sealing member that covers a second main surface of the vibrating part of the piezoelectric resonator plate, wherein
the first sealing member is bonded to the piezoelectric resonator plate and furthermore the second sealing member is bonded to the piezoelectric resonator plate so that the vibrating part of the piezoelectric resonator plate is hermetically sealed, and
the first sealing member and the second sealing member are each made of crystal.
